(19) United States
(12) Patent Application Publication
(10) Pub. No.: US 2025/0133860 A1
(43) Pub. Date: Apr. 24, 2025

(54) METHOD OF MANUFACTURING CARBON PASTE-BASED ELECTRODE FOR OPTO-ELECTRONIC DEVICES AND OPTO-ELECTRONIC DEVICES COMPRISING A CARBON PASTE-BASED ELECTRODE

(71) Applicant: Solaires Entreprises Inc., Victoria (CA)

(72) Inventors: Mozhdeh Forouzandeh, Langford (CA); Maryam Heidariramsheh, Tehran (IR); Nima Taghavinia, Tehran (IR); Hamid Reza Heydarnezhad, Tehran (IR)

(73) Assignee: Solaires Entreprises Inc., Victoria, BC (CA)

(21) Appl. No.: 18/493,700

(22) Filed: Oct. 24, 2023

(51) Int. Cl. H01L 31/0224; H01L 31/048; H01L 31/18

(52) U.S. Cl. CPC H10F 77/211; H10F 19/80; H10F 71/00

(57) ABSTRACT

Provided is method of manufacturing an opto-electronic device, the opto-electronic device comprising a perovskite layer, the method comprising: mixing carbon black and graphite in a solvent at a ratio of 1:1.5 to 3:7 w/w carbon black to graphite, to provide a mixture; drying the mixture to provide a carbon powder; selecting a polymeric binder, which has a softening point between 80° C. to 150° C.; dissolving the polymeric binder in a substituted benzene solvent; mixing the dissolved polymeric binder with the carbon powder at a ratio of 1:2 to 1:5 w/w polymeric binder to carbon powder to provide a conductive paste; coating the perovskite layer with the conductive paste to provide a conductive coating; and drying the conductive coating at 60° C. to 120° C. to provide a conductive layer, thereby manufacturing an opto-electronic device comprising the perovskite layer.

### FIELD

The present technology is directed to a method of manufacturing a robust, conductive electrode which is compatible with a perovskite layer. More specifically, it is a carbon paste-based electrode that can be dried at low temperature and is flexible.

### BACKGROUND

Metal halide perovskite photovoltaics have undergone rapid development in the past few years, with lab efficiency of small area devices reaching 25%, which is competitive with silicon solar cells. At the same time, the pursuit of large area perovskite solar cells has attracted increasing attention in recent years. For the fabrication of large area perovskite films, industrial processes such as slot-die coating, blade coating, sheet to sheet and roll-to-roll fabrication, may be adopted. In such processes, precise adjustments and modulation of several parameters are usually required to obtain a film with sufficiently high quality for photovoltaic applications. The dynamic coating process in these methods may require tight tolerances on the machinery involved in manufacturing. Such methods commonly fabricate a single film during each round of coating.

Thin-film devices are formed using several materials layered upon one another, by printing, coating using polymer inks, or via vacuum deposition on a substrate. A substrate in a thin-film device may include polyethylene terephthalate (PET), polyethylene naphthalate (PEN), fluorine-doped tin oxide (FTO) and indium tin oxide (ITO) as initial layers.

The relatively poor manufacturability of perovskite solar cells, when utilizing current processes, is a significant obstacle preventing broader adoption of these cells. For example, drying of the electrode layers is at temperatures that can degrade the perovskite layer.

Carbon pastes have been developed to substitute with the noble metals like gold in optoelectronic devices like perovskite solar cells. In addition to being compatible with fast roll-to-roll and sheet-to-sheet processes, the carbon electrode is a good option to replace the expensive noble metal electrode due to its good work function, high chemical stability, and carrier transport properties. However, metal-based electrodes are not chemically inert, are expensive and their synthesis is not scalable.

What is needed is a method of manufacturing a conductive layer for use in opto-electronic devices, most notably, perovskite photovoltaic devices. It would be preferable if the method was scalable, was conducted at temperatures that do not degrade the perovskite layer and was low cost. It would be preferable if the conductive layer was flexible.

### SUMMARY

The present technology is a method of manufacturing a conductive layer for use in opto-electronic devices, most notably, perovskite photovoltaic devices. The method is scalable, is conducted at temperatures that do not degrade the perovskite layer and is low cost. The conductive layer is flexible.

In one embodiment, a method of manufacturing a perovskite photovoltaic stack is provided, the method comprising: selecting a stack comprising a perovskite layer, an electron transfer layer, a bottom electrode and a glass substrate; mixing carbon black, graphite and a polymeric binder, which has a softening point between 80° C. to 150° C. in a substituted benzene solvent, wherein the ratio of carbon black to graphite is between 1:1 to 3:7 w/w and the ratio of carbon black and graphite combined to the polymeric binder is between 2:1 and 4:1 w/w, to provide a conductive paste; coating the perovskite layer with the conductive paste to provide a conductive coating; drying the conductive coating to provide a conductive layer; and applying an encapsulation layer to the conductive layer, thereby manufacturing a perovskite photovoltaic stack.

The method may further comprise selecting the polymeric binder from the group consisting of thermoplastic polyurethanes, thermoplastic polyolefin elastomers, styrenic block copolymers, ethylene-vinyl acetate copolymers, and hard-soft segmented copolymers.

The method may further comprise selecting styrene-butadiene-styrene as the polymeric binder.

The method may further comprise selecting chlorobenzene as the substituted benzene solvent.

In the method, the ratio of carbon black to graphite may be 3:7 w/w and the ratio of carbon black and graphite combined to the polymeric binder may be between 3:1 and 4:1 w/w.

In another embodiment, a method of manufacturing an opto-electronic device is provided, the opto-electronic device comprising a perovskite layer, the method comprising: mixing carbon black and graphite in a solvent at a ratio of 1:1 to 3:7 w/w carbon black to graphite, to provide a mixture; drying the mixture to provide a carbon powder; selecting a polymeric binder which has a softening point between 80° C. to 150° C.; dissolving the polymeric binder in a substituted benzene solvent; mixing the dissolved polymeric binder with the carbon powder at a ratio of 1:2 to 1:5 w/w polymeric binder to carbon powder to provide a conductive paste; coating the perovskite layer with the conductive paste to provide a conductive coating; and drying the conductive coating at 60° C. to 120° C. to provide a conductive layer, thereby manufacturing an opto-electronic device comprising the perovskite layer.

The method may further comprise selecting the polymeric binder from the group consisting of thermoplastic polyurethanes, thermoplastic polyolefin elastomers, styrenic block copolymers, ethylene-vinyl acetate copolymers, and hard-soft segmented copolymers.

The method may further comprise selecting styrene-butadiene-styrene as the polymeric binder.

The method may further comprise selecting toluene as the substituted benzene solvent.

The method may further comprise adding a semiconductor material to the carbon powder.

The method may further comprise adding carbon nanowires or carbon nanotubes to the carbon powder.

In the method, the ratio of carbon powder to carbon nanowires or carbon nanotubes may be 10:1 w/w.

In the method, the ratio of carbon black to graphite may be 3:7 w/w and the ratio of carbon black and graphite combined to the polymeric binder may be between 3:1 and 4:1 w/w.

In another embodiment, a conductive paste is provided for coating a perovskite layer, the conductive paste comprising carbon black, graphite and a polymeric binder in a substituted benzene solvent, wherein the ratio of carbon black to graphite is between 1:1 to 3:7 w/w and the ratio of carbon black and graphite combined to the polymeric binder is between 2:1 and 4:1 w/w and wherein the polymeric binder has a softening point between 80° C. to 150° C.

In the conductive paste, the polymeric binder may be styrene-butadiene-styrene.

In the conductive paste the ratio of carbon black to graphite may be 3:7 w/w and the ratio of carbon black and graphite combined to the polymeric binder may be between 3:1 and 4:1 w/w.

In the conductive paste, the substituted benzene solvent may be toluene.

In the conductive paste, the carbon black may be acetylene black.

The conductive paste may further comprise a semiconductor material.

The conductive paste may further comprise nanowires or nanotubes.

### BRIEF DESCRIPTION OF THE FIGURES

FIG. 1 is a schematic of a photovoltaic stack.

FIG. 2 is a block diagram of a method of manufacturing a photovoltaic stack.

FIG. 3 is a block diagram of an alternative embodiment of the method of FIG. 2.

FIG. 4 is a block diagram of another alternative embodiment of the method of FIG. 2.

FIG. 5 is a graph showing the effect of different ratios of carbon powder to polymeric binder on resistivity.

### DESCRIPTION

Except as otherwise expressly provided, the following rules of interpretation apply to this specification (written description and claims): (a) all words used herein shall be construed to be of such gender or number (singular or plural) as the circumstances require; (b) the singular terms “a”, “an”, and “the”, as used in the specification and the appended claims include plural references unless the context clearly dictates otherwise; (c) the antecedent term “about” applied to a recited range or value denotes an approximation within the deviation in the range or value known or expected in the art from the measurements method; (d) the words “herein”, “hereby”, “hereof”, “hereto”, “hereinbefore”, and “hereinafter”, and words of similar import, refer to this specification in its entirety and not to any particular paragraph, claim or other subdivision, unless otherwise specified; (e) descriptive headings are for convenience only and shall not control or affect the meaning or construction of any part of the specification; and (f) “or” and “any” are not exclusive and “include” and “including” are not limiting. Further, the terms “comprising,” “having,” “including,” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. Where a specific range of values is provided, it is understood that each intervening value, to the tenth of the unit of the lower limit unless the context clearly dictates otherwise, between the upper and lower limit of that range and any other stated or intervening value in that stated range, is included therein. All smaller sub ranges are also included. The upper and lower limits of these smaller ranges are also included therein, subject to any specifically excluded limit in the stated range.

Unless defined otherwise, all technical and scientific terms used herein have the same meaning as commonly understood by one of ordinary skill in the relevant art. Although any methods and materials similar or equivalent to those described herein can also be used, the acceptable methods and materials are now described.

### Definitions

Carbon black—in the context of the present technology, carbon black is a form of para-crystalline carbon that has a high surface-area-to-volume ratio.

Acetylene black—in the context of the present technology, acetylene black is a specific form of carbon black and is manufactured by an acetylene thermal decomposition process.

### DETAILED DESCRIPTION

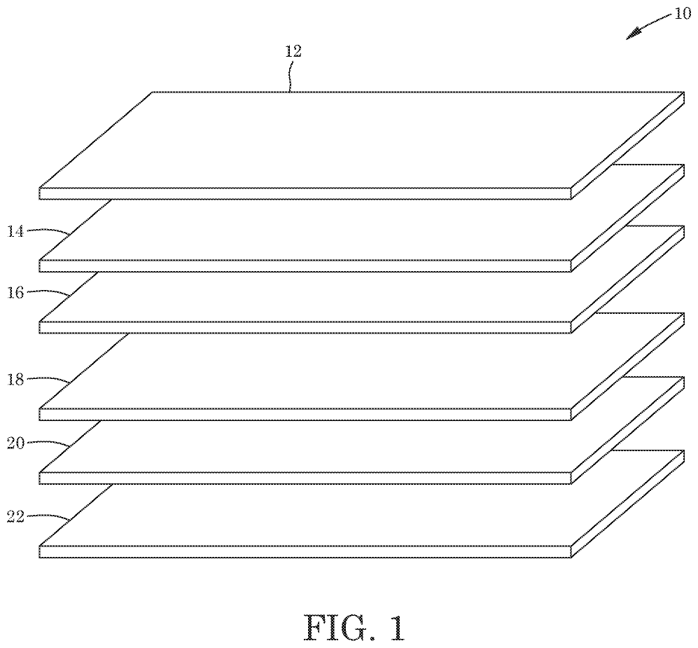

A photovoltaic stack, generally referred to as 10 is shown in FIG. 1. It comprises an encapsulation layer 12, a top electrode 14 or upper conductive layer, a perovskite layer 16, an electron transfer layer 18, a bottom electrode 20 and a glass substrate 22.

The upper conductive layer 14 is made from a conductive paste. In one embodiment, the conductive paste is a carbon paste. The carbon paste is a combination of a carbon powder and a polymeric binder. The carbon powder is carbon black and graphite and optionally carbon nanowires or carbon nanotubes. The polymeric binder is styrene-butadiene-styrene (SBS).

In another embodiment, the conductive paste is a carbon paste, which is a combination of carbon powder and a polymeric binder. The carbon powder is a combination of acetylene black and graphite. The polymeric binder is styrene-butadiene-styrene (SBS).

In another embodiment, the polymeric binder is from one or more of thermoplastic polyurethanes (TPUs), thermoplastic polyolefin elastomers (TPOs), styrenic block copolymers (SBCs), ethylene-vinyl acetate copolymers (EVAs), and hard-soft segmented copolymers.

In another embodiment, the polymeric binder is selected from a polymeric resin with a softening temperature of 80° C. to 150° C.

In another embodiment, the polymeric binder is selected from a polymeric resin with a melting point between 80° C. to 220° C.

In another embodiment, the carbon paste includes a semiconductor material selected from the group comprising: CuInGaS₂, Cu₂ZnSnS₄, chalcogenide semiconductors, CuInS₂, CuPc, Spiro-MeOTAD, oxide nanoparticles and carbon based 2-dimensional material. These are added at a ratio of semiconductor to carbon powder of 1:10 w/w.

The method of manufacturing a photovoltaic stack is shown in FIG. 2. Carbon black was mixed 100 with graphite in a solvent which may be polar or non-polar, for example, but not limited to water, alcohol or an organic solvent such as toluene, using for example, but not limited to ball milling, shear stressing and blending. Ball milling was done at 100 to 400 revolutions per minute (rpm) at room temperature, or at a higher rpm, for example, but not limited to 600 rpm with refrigeration or cooling with liquid nitrogen. The ratio of carbon black to graphite was about 1:1.5 w/w to 1:2 w/w to 3:7 w/w. The mixture was dried 102 to provide a carbon powder. Optionally, the resultant carbon powder was sieved. The polymeric binder was dissolved 104 in an organic solvent, for example, but not limited to ethyl acetate or a substituted benzene such as, but not limited to toluene, chlorobenzene or xylene. The ratio of polymeric binder to solvent was about 1:3 w/w for SBS and toluene. The carbon powder was mixed 106 with the dissolved polymeric binder at a ratio of about 1:1 to about 1:6 w/w, binder:carbon powder, to provide a conductive paste. The conductive paste was then applied 108 to the perovskite layer 16 using for example, but not limited to, blade coating to provide a conductive coating. The conductive coating was dried 110 at between 70° C. and 100° C. for thirty minutes to provide the conductive layer 14 on the perovskite layer 16 of the almost complete photovoltaic stack 10, with only the encapsulation layer being added later to provide a complete photovoltaic stack 10. The drying may also be done at 60° C. to 120° C. for between 15 and 120 minutes. The encapsulation layer 12 was applied 112 to provide the photovoltaic stack 10.

In another embodiment, the ratio of carbon black to graphite was 1:1 w/w.

In one embodiment, toluene was used as the solvent for both the mixing to provide a conductive powder and for dissolving the binder. The resultant conductive paste was applied to the perovskite layer to provide a conductive coating which was dried at room temperature for about 6 to about 12 hours. The ratio of carbon black and graphite to toluene was 1:5 w/w. The ratio of polymeric binder to toluene was 1:3 w/w.

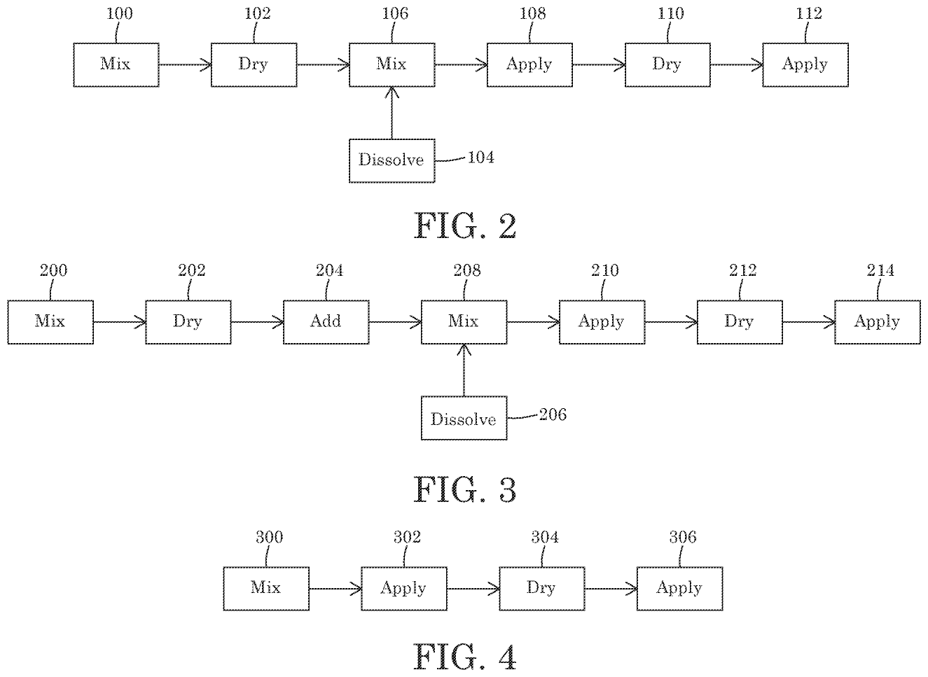

In an alternative embodiment shown in FIG. 3, the carbon black was mixed 200 with graphite in a solvent which may be polar or non-polar, for example, but not limited to water, alcohol or an organic solvent such as toluene, using for example, but not limited to ball milling, shear stressing and blending. The ratio of carbon black to graphite was about 1:1.5 w/w to 1:2 w/w to 3:7 w/w. Ball milling was done at 100 to 400 revolutions per minute (rpm) at room temperature, or at a higher rpm, for example, but not limited to 600 rpm with refrigeration or cooling with liquid nitrogen. The mixture was dried 202. Carbon nanotubes or nanowires were added 204 to the carbon powder at a ratio of about 1:10 w/w, carbon nanotubes or nanowires to carbon powder. Semiconductor material may also be added to the carbon powder at the same ratio of 1:10. The polymeric binder was dissolved 206 in an organic solvent, for example, but not limited to ethyl acetate or a substituted benzene such as, but not limited to toluene, chlorobenzene or xylene. The ratio of polymeric binder to solvent was about 1:3 w/w for SBS and toluene. The carbon powder was mixed 208 with the dissolved polymeric binder at a ratio of about 1:1 to about 1:6 w/w polymeric binder to carbon powder to provide a conductive paste. The conductive paste was then applied 210 to the perovskite layer 16 using for example, but not limited to blade coating. The resultant conductive coating was dried 212 at between 70° C. and 100° C. for thirty minutes to provide the conductive layer 14 on the perovskite layer 16 of the almost complete photovoltaic stack 10, with only the encapsulation layer being added later to provide a complete photovoltaic stack 10. The drying may also be done at 60° C. to 120° C. for between 15 and 120 minutes. The encapsulation layer 12 was applied 214 to provide the photovoltaic stack 10. In another embodiment, the ratio of carbon black to graphite was 1:1 w/w.

In an alternative embodiment shown in FIG. 4, the carbon black was mixed 300 with graphite and polymeric binder in an organic solvent, for example, but not limited to, ethyl acetate or a substituted benzene such as, but not limited to toluene, chlorobenzene or xylene, using for example, but not limited to, ball milling, shear stressing and blending. The ratio of carbon black to graphite was between 1:1.5 to 3:7 w/w and the ratio of carbon black and graphite combined to the polymeric binder was between 2:1 w/w and 4:1 w/w. Ball milling was done at 100 to 400 revolutions per minute (rpm) at room temperature, or at a higher rpm. The resultant conductive paste was then applied 302 to the perovskite layer 16 using for example, but not limited to, blade coating to provide a conductive coating. The conductive coating was dried 304 at room temperature for about 6 to about 12 hours. An encapsulation layer 12 was applied 306 to provide the photovoltaic stack 10. In another embodiment, the ratio of carbon black to graphite was 1:1 w/w.

Regardless of the method used, the resultant conductive layer has the following features: It is compatible with the perovskite layer, has high conductivity, is flexible (which is necessary for making flexible carbon-based perovskite solar cells), is robust (a perovskite layer coated with the conductive layer showed no sign of degradation after 5 minutes immersion in water). The conductive layer also was robust and intact after 10 minutes sonicating in a pH 2 aqueous acid solution and can be dried in temperatures between 70° C. to 100° C. (which is a temperature range that is compatible with all perovskite layers). The conductive layer provides an integrated, even, smooth and crack-free carbon-based electrode.

### Examples

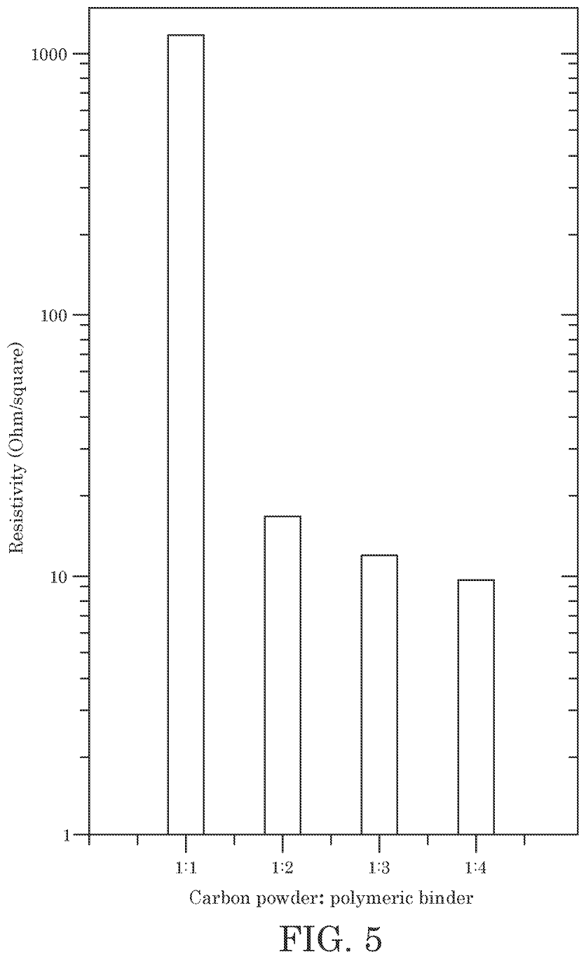

As shown in FIG. 5, different ratios of carbon powder to polymeric binder were studied to determine which ratios provided low resistivity. It was found that a ratio of 2:1, 3:1 and 4:1 w/w carbon powder (carbon black and graphite) to polymeric binder provided low resistivity.

As shown in Table 1, it was further found that a ratio of 9:11, 2:3 and 3:7 w/w of carbon black to graphite provided low resistivity. A ratio of 1:1 w/w provided higher resistivity, but the highest efficiency. 3:7 w/w had the lowest resistivity but slightly lower efficiency that 1:1 w/w.

TABLE 1
Photovoltaic parameters of carbon-based perovskite solar cells
with different ratios of acetylene black (AB) to graphite
(G) in a 3:1 w/w carbon powder to polymeric binder ratio.

| Ratio of AB | | |
|---|---|---|
| to G w/w | Resistivity | Efficiency |
| 1:0 | 434 | 6.7 |
| 1:1 | 4.53 | 14.75 |
| 9:11 | 3.92 | 13.9 |
| 2:3 | 3.85 | 14.15 |
| 3:7 | 3.57 | 14.28 |
| 0:1 | 61.47 | 6.24 |

As shown in Table 2, a ratio of acetylene black to graphite of 1:4 at all ratios of carbon powder to polymeric binder provided high resistivity. The lowest resistivity for a ratio of acetylene black to graphite of 3:7 w/w was at a 3:1 and 4:1 w/w ratio of carbon powder to polymeric binder. In terms of efficiency, a ratio of 3:7 for acetylene black to graphite and a ratio of 3:1 w/w carbon powder to polymeric binder provided the best efficiency. The 2:1 and 5:1 w/w ratios of carbon powder to polymeric binder had lower efficiency.

TABLE 2
Photovoltaic properties of carbon-based perovskite solar cells
with different ratios of carbon powder to polymeric binder
and different ratios of acetylene black to graphite.

| | Ratio of carbon | | |
|---|---|---|---|
| | powder to | | |
| Ratio of AB | polymeric | | |
| to G w/w | binder w/w | Resistivity | Efficiency |
| 3:7 | 2:1 | 7.14 | 14.16 |
| 1:4 | 2:1 | 13.57 | 14.65 |
| 3:7 | 3:1 | 6.94 | 17.04 |
| 1:4 | 3:1 | 17.55 | 15.61 |
| 3:7 | 4:1 | 6.13 | 15.47 |
| 1:4 | 4:1 | 13.26 | 15.08 |
| 3:7 | 5:1 | 8:1 | 15.31 |
| 1:4 | 5:1 | 16.05 | 16.16 |

Water contact angles were also studied, with a high contact angle being superior to a low contact angle. The ratios of carbon black to graphite were 1:0, 1:1, 9:11, 2:3, 7:13, 3:7, and 0:1 w/w. The highest angle was provided by a ratio of 7 parts carbon black to 13 parts graphite w/w. The lowest water contact angle was provided by a ratio of 1:0 w/w, followed by 2:3 w/w.

The effect of different non-polar solvents was studied, and it was found that toluene, xylene and chlorobenzene were suitable solvents. As shown in Table 3, of the non-polar solvents, chlorobenzene provided the lowest resistivity while toluene had the highest efficiency. Toluene also provided the highest water contact angle.

TABLE 3
Photovoltaic properties of carbon-based perovskite
solar cells with different non-polar solvents.

| Solvent | Resistivity | Efficiency |
|---|---|---|
| Toluene | 5.01 | 16.5 |
| Xylene | 5.11 | 13.97 |
| Chlorobenzene | 3.46 | 14.71 |

As shown in Table 4, the lowest resistivity was found at an acetylene black to graphite ratio of 3:7 w/w. Similarly, the highest efficiency was at an acetylene black to graphite ratio of 3:7 w/w.

TABLE 4
Photovoltaic properties of carbon-based perovskite solar cells
with different ratios of acetylene black to graphite at a
ratio of 3:1 w/w of carbon powder to polymeric binder.

| Ratio of AB | | |
|---|---|---|
| to G w/w | Resistivity | Efficiency |
| 1:4 | 11.31 | 14.38 |
| 6:19 | 7.86 | 14.67 |
| 27:73 | 4.94 | 15.56 |
| 3:7 | 3.78 | 15.96 |

On the basis of the results, it appeared that a ratio of 3:1 or 4:1 w/w carbon powder to polymeric binder provided superior results to 2:1 or 5:1 w/w. It appeared that a ratio of 3:7 w/w carbon black or acetylene black to graphite provided the lowest resistivity and generally the highest efficiency, with only a 1:1 w/w ratio being slightly superior in efficiency, but with higher resistivity. No one solvent outperformed the others, however, xylene was inferior to toluene and chlorobenzene both in terms of resistivity and efficiency.

While example embodiments have been described in connection with what is presently considered to be an example of a possible most practical and/or suitable embodiment, it is to be understood that the descriptions are not to be limited to the disclosed embodiments, but on the contrary, is intended to cover various modifications and equivalent arrangements included within the spirit and scope of the example embodiment. Those skilled in the art will recognize or be able to ascertain using no more than routine experimentation, many equivalents to the specific example embodiments specifically described herein. Such equivalents are intended to be encompassed in the scope of the claims, if appended hereto or subsequently filed.

1. A method of manufacturing a perovskite photovoltaic stack, the method comprising: selecting a stack comprising a perovskite layer, an electron transfer layer, a bottom electrode and a glass substrate; mixing carbon black, graphite and a polymeric binder, which has a softening point between 80° C. to 150° C. in a substituted benzene solvent, wherein the ratio of carbon black to graphite is between 1:1 to 3:7 w/w and the ratio of carbon black and graphite combined to the polymeric binder is between 2:1 and 4:1 w/w, to provide a conductive paste; coating the perovskite layer with the conductive paste to provide a conductive coating; drying the conductive coating to provide a conductive layer; and applying an encapsulation layer to the conductive layer, thereby manufacturing a perovskite photovoltaic stack.

2. The method of claim 1, further comprising selecting the polymeric binder from the group consisting of thermoplastic polyurethanes, thermoplastic polyolefin elastomers, styrenic block copolymers, ethylene-vinyl acetate copolymers, and hard-soft segmented copolymers.

3. The method of claim 1, further comprising selecting styrene-butadiene-styrene as the polymeric binder.

4. The method of claim 3, further comprising selecting chlorobenzene as the substituted benzene solvent.

5. The method of claim 4, wherein the ratio of carbon black to graphite is 3:7 and the ratio of carbon black and graphite combined to the polymeric binder is between 3:1 and 4:1 w/w.

6. A method of manufacturing an opto-electronic device, the opto-electronic device comprising a perovskite layer, the method comprising: mixing carbon black and graphite in a solvent at a ratio of 1:1 to 3:7 w/w carbon black to graphite, to provide a mixture; drying the mixture to provide a carbon powder; selecting a polymeric binder, which has a softening point between 80° C. to 150° C.; dissolving the polymeric binder in a substituted benzene solvent; mixing the dissolved polymeric binder with the carbon powder at a ratio of 1:2 to 1:5 w/w polymeric binder to carbon powder to provide a conductive paste; coating the perovskite layer with the conductive paste to provide a conductive coating; and drying the conductive coating at 60° C. to 120° C. to provide a conductive layer, thereby manufacturing an opto-electronic device comprising the perovskite layer.

7. The method of claim 6, further comprising selecting the polymeric binder from the group consisting of thermoplastic polyurethanes, thermoplastic polyolefin elastomers, styrenic block copolymers, ethylene-vinyl acetate copolymers, and hard-soft segmented copolymers.

8. The method of claim 6, further comprising selecting styrene-butadiene-styrene as the polymeric binder.

9. The method of claim 8, further comprising selecting toluene as the substituted benzene solvent.

10. The method of claim 9, further comprising adding a semiconductor material to the carbon powder.

11. The method of claim 10, further comprising adding carbon nanowires or carbon nanotubes to the carbon powder.

12. The method of claim 11, wherein the ratio of carbon powder to carbon nanowires or carbon nanotubes is 10:1 w/w.

13. The method of claim 12, wherein the ratio of carbon black to graphite is 3:7 w/w and the ratio of carbon black and graphite combined to the polymeric binder is between 3:1 and 4:1 w/w.

14. A conductive paste for coating a perovskite layer, the conductive paste comprising carbon black, graphite and a polymeric binder in a substituted benzene solvent, wherein the ratio of carbon black to graphite is between 1:1 to 3:7 w/w and the ratio of carbon black and graphite combined to the polymeric binder is between 2:1 and 4:1 w/w and wherein the polymeric binder has a softening point between 80° C. to 150° C.

15. The conductive paste of claim 14, wherein the polymeric binder is styrene-butadiene-styrene.

16. The conductive paste of claim 15, wherein the ratio of carbon black to graphite is 3:7 w/w and the ratio of carbon black and graphite combined to the polymeric binder is between 3:1 and 4:1 w/w.

17. The conductive paste of claim 16, wherein the substituted benzene solvent is toluene.

18. The conductive paste of claim 17, wherein the carbon black is acetylene black.

19. The conductive paste of claim 18, further comprising a semiconductor material.

20. The conductive paste of claim to 19, further comprising nanowires or nanotubes.
